(19) United States
(12) Patent Application Publication
(10) Pub. No.: US 2024/0313497 A1
(43) Pub. Date: Sep. 19, 2024

(54) REFLECTIVE FIBER AMPLIFIER IN A CASCADED TOPOLOGY FOR OPERATION IN C-BAND AND L-BAND WAVELENGTH RANGES

(71) Applicant: II-VI Delaware, Inc., Wilmington, DE (US)

(72) Inventors: Ian Peter McClean, Brixham (GB); Martin R. Williams, Big Flats, NY (US)

(73) Assignee: II-VI Delaware, Inc., Wilmington, DE (US)

(21) Appl. No.: 18/122,188

(22) Filed: Mar. 16, 2023

(51) Int. Cl. H01S 3/067

(52) U.S. Cl. CPC H01S 3/0677; H01S 3/06758; H01S 2301/04

(57) ABSTRACT

A cascaded arrangement of optical amplifying stages is used to provide efficient amplification of signals within an extended wavelength range in a relatively compact configuration. A wavelength selective filter is positioned at the output of a first amplifier stage and used to direct amplified signals within a longer wavelength range (e.g., L-band) into a second amplifier stage, thus forming a cascaded configuration of the first and second amplifier stages. The second stage imparts an additional level of gain to the signals within the longer wavelength range, and an optical combiner may be used to direct both sets of amplified signals along a common output path.

### TECHNICAL FIELD

Disclosed herein is a fiber-based optical amplifier formed in a reflective configuration and using a cascaded arrangement of the C-band and L-band components.

### BACKGROUND

Architectures of erbium-doped fiber amplifiers (EDFAs) currently exist that support applications based on the use of both the C-band wavelength range (i.e., 1525-1570 nm) and the L-band wavelength range (i.e., 1570-1625 nm), but have been found to be inefficient. The proposed architectures typically use single-direction gain paths, require substantially higher pump power (as compared to a common C-band EDFA), and exhibit signal wavelength dependence on the pump power.

Traditional L-band versions of these amplifiers are optically more complicated, having two gain stages requiring more optical components and considerably higher total pump power due to more inefficient conversion and the need at least for two separate sections of gain fiber (each section needing to be pumped). Additionally, L-band amplifiers need to apply the pump beam at the input termination of each fiber section in order to create a sufficient amount of gain to overcome all of the passive loss attributed to the long fiber lengths required for L-band amplification.

### SUMMARY OF THE DISCLOSURE

Disclosed herein are architectures for EDFAs that address at least the limitations described above and provide amplification for input signals operating in the C-band wavelength range and/or the L-band wavelength range.

In particular, a cascaded arrangement of amplifying elements is utilized, where an input signal to be amplified (within the extended wavelength range, such as the C+L bands) is coupled into a first amplifier stage, where the first stage provides sufficient amplification for a first, shorter wavelength portion of a relatively wide wavelength range. At least the signals within a second, longer wavelength portion of the wavelength range thereafter pass through a second amplifier stage (thus forming a cascaded configuration), with the signals amplified within both stages combined along a common output path. In one case, a wavelength selective filter is positioned at the output of the first amplifier stage and used to direct amplified signals within the shorter wavelength range (e.g., in the C-band range) along the output path, with the initially-amplified signals within a longer range (e.g., L-band) directed into the second amplifier stage. In another case, the output from the first amplifier stage is directly coupled into the second amplifier stage, with a wavelength-selective filter disposed within this second stage to re-direct shorter wavelength signals along the output signal path while presenting the longer-wavelength signals for further amplification.

A reduction in size and component count of the disclosed cascaded amplifier is provided by forming the L-band amplifier in a reflective topology, where a single section of gain fiber coupled to a reflective element at its far-end termination simulates the performance of an amplifier with twice the fiber length (or an amplifier based upon a two-stage arrangement). In some embodiments, the C-band portion of the EDFA may also be formed in a reflective topology.

An example embodiment of the disclosed optical amplifier may comprise a cascaded optical amplifier including a combination of a first amplifier arrangement and a second amplifier arrangement for imparting gain to input signals operating at wavelengths within a defined wavelength range. The first amplifier arrangement itself being responsive to an input optical signal operating at a wavelength within the defined wavelength range and including at least one section of rare-earth doped fiber. The first amplifier arrangement receives as a second input a pump beam and is configured to generate a first amplified output signal. The second amplifier arrangement is coupled to the first amplifier arrangement and is responsive at least to amplified signals within a longer wavelength portion of the defined wavelength range. The second amplifier arrangement comprises at least one section of rare-earth doped fiber and a reflective element disposed at a far-end termination of the at least one section of rare-earth doped fiber to create an optical path length greater than a physical length of the at least one section of rare-earth doped fiber for providing amplification of signals passing therethrough. The cascaded arrangement also includes an optical filter disposed along the signal path between the output of the first amplifier arrangement and the at least one section of rare-earth doped fiber of the second amplifier arrangement, the optical filter directing signals operating within the longer wavelength portion into the at least one section of rare-earth doped fiber of the second amplifier arrangement, and an optical combiner configured to couple the outputs from the first and second amplifier arrangements onto a common output path of the cascaded optical amplifier.

Other and further embodiments may become apparent during the course of the following discussion and by reference to the accompanying drawings.

### BRIEF DESCRIPTION OF THE DRAWINGS

Referring now to the drawings, where like numerals represent like components in the presented drawing set,

FIG. 1 contains a block diagram of a conventional fiber-based optical amplifier;

FIG. 2 contains a block diagram of an example of the disclosed cascaded, reflective optical amplifier;

FIG. 3 illustrates in detail a first embodiment of the cascaded, reflective optical amplifier of FIG. 2;

FIG. 4 shows an alternative configuration of the embodiment of FIG. 3, incorporating a wavelength-selective filter to simplify the topology of the fiber-based amplifier;

FIG. 5 illustrates in detail a second embodiment of the cascaded, reflective optical amplifier of FIG. 2; and

FIG. 6 shows an alternative configuration of the embodiment of FIG. 5, again incorporating a wavelength-selective filter to simplify the topology.

### DETAILED DESCRIPTION

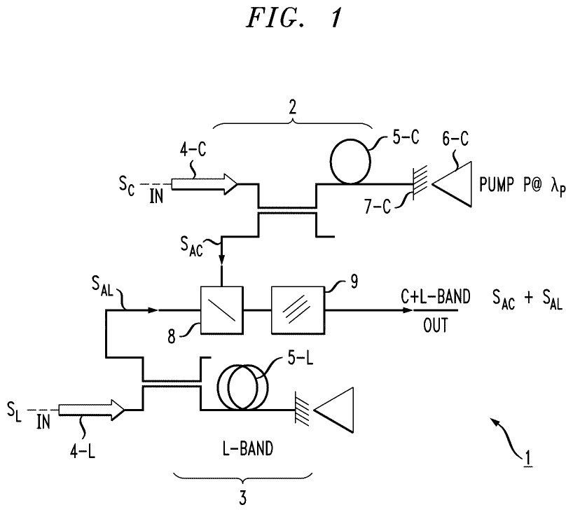

FIG. 1 is an illustration of a conventional EDFA 1 that is configured to operate across both the C-band wavelength range (1525-1570 nm) and the L-band wavelength range (1570-1625 nm). As shown, EDFA 1 is basically a combination of an independent C-band amplifier 2 and an independent L-band amplifier 3. In the arrangement of FIG. 1, both amplifiers are formed in a reflective configuration and each includes a length of rare-earth doped fiber 5 (referred to at times in this description as a “gain fiber”). While Erbium (Er) is a common dopant used for this purpose, other rare-earth dopants (e.g., Ytterbium, Holmium, Thulium, etc.) may be used as well.

A C-band input signal (S_{C}) is introduced into amplifier 2 through an isolator 4-C and similarly, an L-band input signal (S_{L}) is coupled into amplifier 3 through an isolator 4-L. A first pump source 6-C is used to provide a pump beam P operating at a wavelength λ_{P} selected to energize the dopant ions and provide gain to the applied input signal passing through C-band amplifier 2. In this reflective topology, pump source 6-C is co-located with a reflective element 7-C so that pump beam P enters gain fiber 7-C in a counter-propagating direction with respect to the initial propagation direction of input signal S_{C}. Indeed, by virtue of including reflective element 7-C, the C-band signal passes through gain fiber 5-C twice (and so receives an additional amount of gain during the second pass). An amplified C-band signal S_{AC} is shown as exiting amplifier 2.

L-band amplifier 3 includes similar components as C-band amplifier 2, which function in a similar manner, the exception being that the section of gain fiber 5-L needs to be substantially longer than gain fiber 5-C in order to provide an optical path length that is long enough to adequately amplify input signals within the L-band wavelength range. Advantageously, the use of a reflective configuration for L-band amplifier 3 essentially doubles the length of the optical path along which amplification is performed and as a result can take the form of a more compact arrangement than would otherwise be required (particularly for providing adequate amplification of input signals within the longer wavelength portion of the L-band range). The amplified output from L-band amplifier 3 is denoted as S_{AL} in FIG. 1.

An optical combiner 8 is used to direct both amplified signals S_{AC} and S_{AL} onto a common optical output signal path O. A gain-flattening filter (GFF) 9 may be included along output path O to reduce non-uniformities in the gain profile across both wavelength ranges. Keeping in mind this typical configuration of an EDFA that is operable over the combination of the C-band and L-band wavelength ranges, various embodiments of compact, cascaded dual-band amplifiers formed in accordance with the present disclosure will be described in detail below.

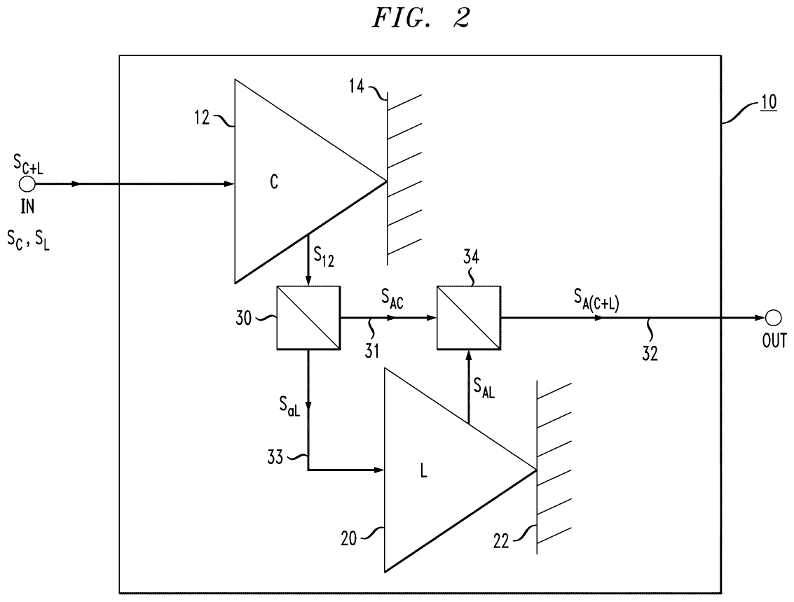

FIG. 2 illustrates a basic configuration of a cascaded, reflective EDFA 10 formed in accordance with the principles of the present disclosure that is suitable for operation across, for example, the C+L bands in an arrangement that is more compact (and typically less expensive) than conventional arrangements, such as that described above. In particular, EDFA 10 comprises a first amplifier arrangement 12 that is configured as a reflective amplifier in this example by virtue of including a reflective element 14 at a far-end termination of a section of gain fiber (not shown here, but illustrated in various ones of the following drawings). EDFA 10 further comprises a second amplifier arrangement 20 that is also configured as a reflective amplifier, with a reflective element 22 disposed at a far-end termination of the gain fiber within second amplifier arrangement 20.

As shown in FIG. 2, both C-band input signals S_{C} and L-band input signals S_{L} are applied as inputs to a common input port IN and directed into first amplifier arrangement 12. The reference S_{C+L} is used hereafter to emphasize that an input signal to the disclosed cascaded amplifier arrangement could be either a C-band signal S_{C} or an L-band signal S_{L}. The use of a common port for signals in both bands is a clear distinction with respect to the prior art, where the C-and L-band input signals are applied as inputs to separate amplifier configurations. In accordance with the disclosed cascaded configuration, the amplified output from first amplifier arrangement 12 is applied as an input to a wavelength-selective filter 30 that is configured to direct C-band amplified signals S_{AC} along a first signal path 31, while directing L-band signals (which have been initially amplified within first amplifier 12 and denoted as S_{aL} in the figures) along a second signal path 33 and applied as an input to second amplifier arrangement 20. Wavelength-selective filter 30 may comprise a dichroic filter or similar type of wavelength bandpass filtering component.

Second amplifier 20 includes a relatively long length of gain fiber (i.e., substantially longer than the gain fiber used in first amplifier 12), and is formed in a reflective configuration with a reflective element 22 disposed at a far-end termination of the gain fiber. By allowing input signal S_{aL} to pass through the gain fiber twice (in the presence of a pump beam), an amplified L-band signal S_{AL} with a sufficient level of gain exits second amplifier 20. A beam combiner 34 is disposed along an output path 32 of cascaded amplifier 10 and receives as separate inputs C-band amplified signals S_{AC} propagating along path 31 and L-band amplified signals S_{AL} from second amplifier 20. The output from cascaded C+L bands amplifier 10 is shown as S_{A(C+L)} in FIG. 2, providing amplification of both C-band and L-band input signals with a reduced number of components (and a physically smaller arrangement) in comparison to the prior art.

It is to be understood that the particulars of wavelength selective filter 30 may be modified to use any suitable wavelength as a point of demarcation between the two paths; said another way, a strict division into C-band and L-band wavelength ranges is not required. In a more general description of the disclosed cascaded amplifier, wavelength selective filter 30 is configured to direct amplified signals within a first, shorter wavelength range along signal path 31 and amplified signals within a second, longer wavelength range along signal path 33. Thus, while the following discussion may refer to wavelength selective filter 30 as being used to separate initially amplified input signals into either C-band or L-band signals, the pair of outputs from filter 30 more generally include a first output within a first, shorter wavelength range and a second output within a second, longer wavelength range.

By virtue of using the cascaded pair of amplifiers in accordance with the present disclosure, first amplifier 12 functions as either a full amplifier for C-band input signals, or as a “first stage” of amplification for longer wavelength signals (e.g., L-band) signals, eliminating the need for separate amplification paths for input signals along the combined C+L bands.

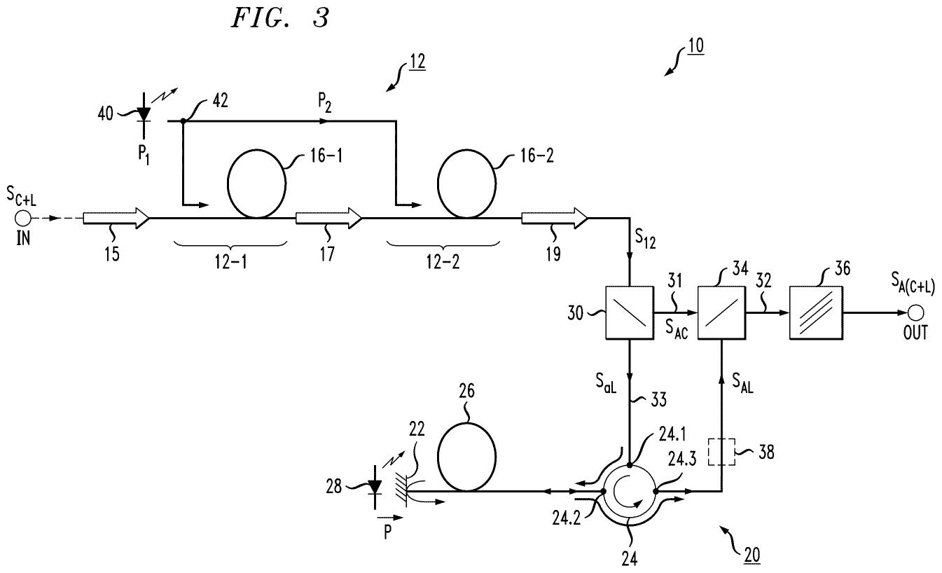

FIG. 3 illustrates a first embodiment of a cascaded, reflective C+L bands amplifier 10 as briefly described above in association with generalized configuration of FIG. 2. In this particular embodiment, first amplifier 12 is configured as a conventional two-stage amplifier (instead of a reflective arrangement), with a pump source 40 disposed to inject a pump beam P into each amplifier stage. A power splitter 42 is disposed at the output of pump source 40 and used to a direct a first portion of pump energy P₁ into a first amplifier stage 12-1 and a second, remaining portion of pump energy P₂ into a second amplifier stage 12-2. The single input port of cascaded, reflective amplifier 10 is used to receive inputs signals spanning the complete C-band and L-band wavelength ranges (S_{C+L}), as discussed above with respect to the arrangement of FIG. 2. In particular, S_{C+L} is shown as applied as an input to first amplifier stage 12-1 after passing through an input isolator 15, where input signal S_{C+L} will be directed into a first section of doped (gain) fiber 16-1. The combination of pump P₁ with the dopant ions in gain fiber 16-1 provides an initial amount of gain to input signal S_{C+L}. The amplified output is thereafter coupled into second amplifier stage 12-2 (usually after passing through an inter-stage isolator 17). Second pump beam P₂ is used as a second input to second amplifier stage 12-2, with both the amplified signal and pump beam coupled into a second section of gain fiber 16-2.

The amplified output from second amplifier stage 12-2, after passing through an output isolator 19, is defined as the amplified output signal S₁₂ from first amplifier 12 and is thereafter applied as an input to wavelength selective filter 30. As discussed above, an input signal within a defined, shorter wavelength region (e.g., C-band) will be sufficiently amplified within first amplifier 12 and is thereafter directed by wavelength filter 30 along a first signal path 31 as amplified output signal S_{AC}.

When the signal applied as an input to cascaded amplifier 10 is within the longer wavelength region (e.g., L-band), an initial amount of amplification (denoted as S_{aL}) will occur within first amplifier 12, but the level of gain achieved at this longer wavelength range is insufficient for useful applications. Thus, wavelength filter 30 directs this initially-amplified L-band signal S_{aL} into second amplifier 20. As shown in the specific example of FIG. 3, signal S_{aL} is directed along a second signal path 33 which is coupled to the input of second amplifier 20.

In this particular configuration of cascaded, reflective amplifier 10 as shown in FIG. 3, second amplifier 20 includes a three-port optical circulator 24, where incoming signal S_{aL} is coupled into an input port 24.1 of circulator 24. A relatively long section of gain fiber 26 is coupled to a bi-directional port 24.2 of circulator 24, such that the propagating signal S_{aL} will be directed through circulator 24 and exit into gain fiber 26. Reflective element 22 is shown as coupled to a far-end termination of gain fiber 26. A pump source 28 is positioned in combination with reflective element 22 and used to direct a pump beam P operating at a suitable wavelength λ_{P} into gain fiber 26.

By virtue of using a reflective arrangement for amplifying longer-wavelength signals, the optical path length along which amplification occurs will be essentially twice that of the physical length of the gain fiber (useful in providing sufficient signal amplification at the longer wavelength end of the L-band range). The amplified output S_{AL} from gain fiber 26 is shown in FIG. 3 coupled back into bi-directional port 24.2 of circulator 24, so that it propagates through circulator 24 and exits from output port 24.3, which is also defined as the output from second amplifier 20.

Both C-band amplified signal S_{AC} propagating along first signal path 31 and L-band amplified signal S_{AL} exiting second amplifier are shown in FIG. 3 as being applied as separate inputs to signal combiner 34. In this embodiment of cascaded, reflective amplifier 10, a gain-flattening filter 36 is shown as disposed along the output signal path after combiner 34. It is also possible to include a wavelength-selective filter 38 along the output signal path from second amplifier 20, where this filter is configured to eliminate any remaining shorter wavelength range (C-band) ASE that may also appear along with the amplified L-band output S_{AL} from second amplifier 20. Additionally, it is also possible to utilize a pair of gain-flattening filters, one particularly configured to for use with C-band amplified signals and the other for L-band amplified signals.

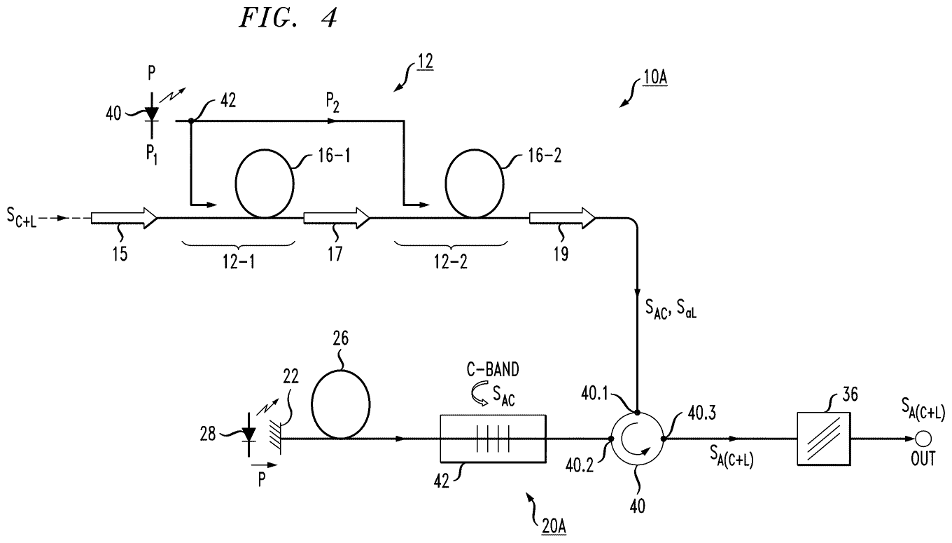

An alternative configuration of the embodiment of FIG. 3 is illustrated in FIG. 4. Here, fiber-based amplifier 10A is configured to reduce the number of discrete elements used to direct both the L-band amplified signal S_{AL} and the C-band amplified signal S_{AC} onto output signal path 32. In particular, the output from first amplifier 12 (comprising both amplified C-band signal S_{AC} and initially-amplified L-band signal S_{aL}) are directed into an input port 40.1 of an included optical circulator 40. Both signals are thereafter directed through optical circulator 40 to exit at bidirectional port 40.2, where a second amplifier 20A is coupled to bidirectional port 40.2. In accordance with this particular arrangement, a wavelength-selective filter 42 (for example, a fiber Bragg grating, FBG) is included along the signal path and configured to reflect C-band wavelengths, while allowing L-band wavelength signals to pass through. Therefore, as shown, C-band amplified signal S_{AC} is reflected by filter 42, re-entering bidirectional port 40.2 of optical circulator 40 and propagating through to exit at output port 40.3, which is coupled to output signal path 32 of amplifier 10A.

Referring again to wavelength-selective filter 42, recall that any initially amplified L-band signal will pass through filter 42 relatively unimpeded. Therefore, initially amplified signal S_{aL} will continue along the path to enter gain fiber 26 and be amplified, reflected, and amplified a second in the same manner as described above in association with amplifier 10 of FIG. 3. The final amplified L-band signal S_{AL} again passes through wavelength-selective filter 42 unimpeded, and will be coupled into bidirectional port 40.2 of optical circulator 40. Thereafter, amplified L-band signal S_{AL} propagates through optical circulator 40 to exit at output port 40.3 to be directed along output signal path 32 with amplified C-band signal SAL. Gain-flattening filter 36 may be included along output path 32 and used in the same manner as described above.

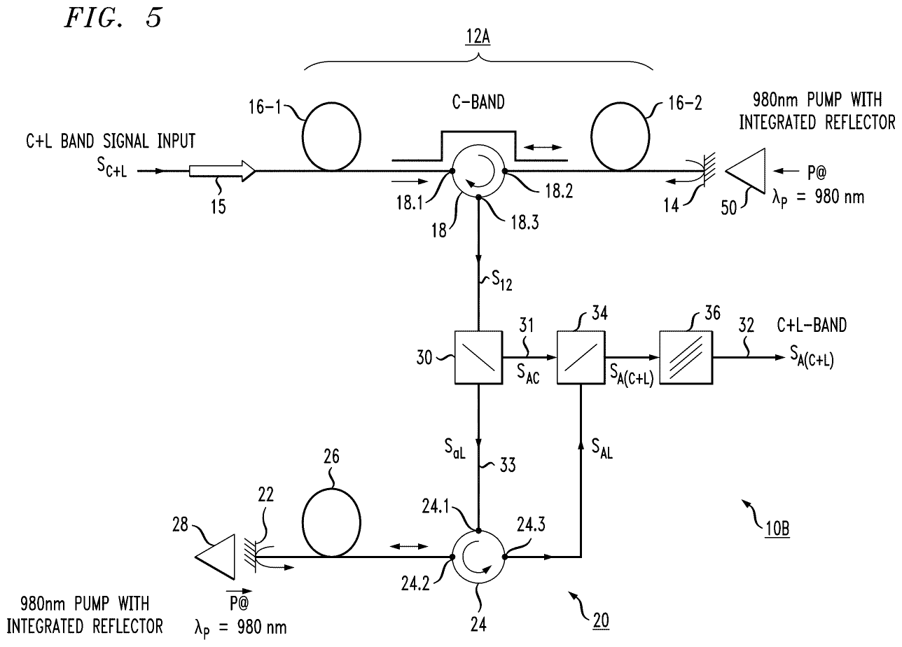

FIG. 5 illustrates an alternative embodiment of a cascaded, reflective optical amplifier 10B that is similar to the arrangement described above in association with FIG. 3, except in this case first amplifier 12 is formed as a reflective first amplifier 12A. The use of a reflective first amplifier 12A eliminates the need for intermediate and output optical isolators and a pump beam power splitter (the isolators and power splitter as shown in FIG. 3), as well as coupling components for providing both the input and pump to each amplifier stage. Instead, a pump source 50 is shown in the arrangement of FIG. 5 as integrated with reflective element 14, directing a counter-propagating pump beam P into second gain fiber section 16-2 through the reflective element.

A three-port optical circulator 18 is included in reflective first amplifier 12A to direct the flow of signals into and out of reflective amplifier 12A. Thus, similar to the use of circulator 24 within second amplifier 20, second gain fiber section 16-2 is coupled to a bi-directional port 18.2 of circulator 18, allowing for the reflected, second pass of input signal exiting fiber section 16-2 to be coupled into circulator 18 and propagate therethrough to exit at an output port 18.3, which is coupled to the input of wavelength selective filter 30.

The various other elements of amplifier 10B not discussed in detail (for example, wavelength selective filter 30 and second amplifier 20) function in a manner similar to that of amplifier 10 of FIG. 3, presenting suitable amplified output signals across the C+L bands along output signal path 32, the amplified output signals again shown as S_{A(C+L)}.

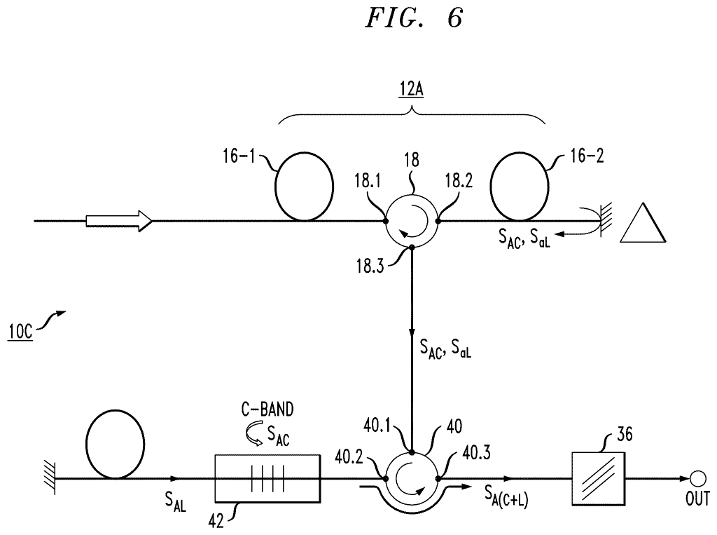

FIG. 6 illustrates an alternative, cascaded amplifier arrangement 10C, which as shown provides the component reduction as in the arrangement of FIG. 4 in combination with the reflective first amplifier 12A of FIG. 5. The particular topology of amplifier 10C is thus relatively compact in two aspects; namely, using a reflective amplifiers for both C-band and L-band amplification, and locating the wavelength selective filter within the second amplifier to simplify the introduction of both amplified signals to the output path of the amplifier.

Although the principles disclosed and discussed thus far have been illustrated and described with respect to forming an Erbium-doped fiber amplifier (EDFA), where it is known that the Er dopant is able to generate amplification in the C+L bands in the presence of a pump beam having a wavelength of 980 nm (or possibly 1480 nm), the disclosed cascaded amplifier arrangement is useful in amplifying various other optical signal wavelength ranges. For example, an arrangement may have transmissions within the S-band in combination with C-band (and/or possibly L-band), where wavelength selective filters 30, 42 would be modified accordingly. Indeed, in various ones of these other arrangements it is possible to utilize a tunable wavelength selective filter, providing the user to ability to control the wavelength defining the separation between the shorter and longer wavelength portions of an input signal range.

Additionally, it will be readily apparent to those of ordinary skill in the art that other embodiments and examples may perform similar functions and/or achieve like results as the cascaded, reflective optical amplifiers described above. All such equivalent embodiments and examples are within the spirit and scope of this disclosure, are contemplated thereby, and are intended to be covered by the claims appended hereto.

What is claimed is:

1. A cascaded optical amplifier for imparting gain to input signals operating at wavelengths within a defined wavelength range, the cascaded optical amplifier comprising:
a first amplifier arrangement responsive to an input optical signal operating at a wavelength within the defined wavelength range and including at least one section of rare-earth doped fiber, the at least one section of rare-earth doped fiber receiving as a second input a pump beam operating at a wavelength selected to provide amplification of the input signal, creating a first amplified output signal from the first amplifier arrangement;
a second amplifier arrangement responsive to at least to first amplified output signals within a longer wavelength portion of the defined wavelength range, the second amplifier arrangement comprising at least one section of rare-earth doped fiber and a reflective element disposed at a far-end termination of the at least one section of rare-earth doped fiber to create an optical path length greater than a physical length of the at least one section of rare-earth doped fiber for providing amplification of the first amplified output signal within the longer wavelength portion, creating a second amplified output signal from the second amplifier arrangement;
an optical filter disposed along the signal path between the output of the first amplifier arrangement and the at least one section of rare-earth doped fiber of the second amplifier arrangement, the optical filter directing signals operating within the longer wavelength portion into the at least one section of rare-earth doped fiber of the second amplifier arrangement; and
an optical combiner configured to couple the outputs from the first and second amplifier arrangements onto a common output path of the cascaded optical amplifier.

2. The cascaded optical amplifier of claim 1, wherein the optical filter is a wavelength-selective bandpass filter configured to direct amplified signals within a shorter wavelength portion of the defined wavelength range along a first signal path toward the optical combiner, and direct amplified signals within the longer wavelength portion into the second amplifier arrangement.

3. The cascaded optical amplifier of claim 2, wherein the wavelength-selective bandpass filter comprises a dichroic filter.

4. The cascaded optical amplifier of claim 1, wherein the optical filter is a reflective optical filter disposed at the input to the at least one section of rare-earth doped fiber of the second amplifier arrangement, the reflective optical filter configured to reflect amplified signals within the shorter wavelength range and pass amplified signals within the longer wavelength range into the at least one section of rare-earth doped fiber of the second amplifier arrangement.

5. The cascaded optical amplifier of claim 4, wherein the reflective optical filter comprises a fiber Bragg grating configured to reflect amplified signals within the shorter wavelength range and pass amplified signals within the longer wavelength range.

6. The cascaded optical amplifier of claim 4, further comprising:
a three-port optical circulator disposed to receive at a first input port the first amplified signal formed by the first amplifier arrangement, the first amplified signal exiting at the bi-directional port of the optical circulator and coupled into the reflective optical fiber, with amplified signals within both the shorter wavelength range and longer wavelength range coupled into the bidirectional port and directed through the optical circulator to exit at the output port, forming the optical combiner.

7. The optical amplifier of claim 1, further comprises a gain flattening filter disposed along the common output path.

8. The optical amplifier of claim 1, wherein the optical filter comprises a tunable filter for adjusting a wavelength defining a boundary between the first, shorter wavelength range and the second, longer wavelength range.

9. The optical amplifier of claim 1, wherein the first, shorter wavelength range comprises a C-band wavelength range and the second, longer wavelength range comprises an L-band wavelength range.

10. The optical amplifier of claim 1, wherein the first amplifier arrangement is configured as a reflective arrangement and further comprises a reflective element disposed at a far-end termination of the at least one section of rare-earth doped fiber.

11. The optical amplifier of claim 1, wherein the second amplifier arrangement further comprises a three-port optical circulator including an input port, a bi-directional signal port, and an output port,
the second signal path output of the wavelength selective filter coupled to the input port of the three-port optical circulator such that amplified signals within the second, longer wavelength range propagate through the optical circulator and exit at the bidirectional port,
the at least one section of rare-earth doped fiber coupled to the bi-directional port of the three-port optical circulator and used to create additional amplification of signals within the second, longer wavelength range and thereafter direct a twice-amplified signal within the second, longer wavelength range into the bi-directional port of the optical circulator so as to propagate therethrough and exit at the output port of the optical circulator as the amplified output of the second amplifier arrangement.

12. The optical amplifier as defined in claim 1, wherein each section of rare-earth doped fiber comprises a section of erbium-doped fiber and each pump beam operates at a wavelength of about 980 nm.
